(19) United States
(12) Patent Application Publication
(10) Pub. No.: US 2025/0085625 A1
(43) Pub. Date: Mar. 13, 2025

(54) NANOIMPRINT LITHOGRAPHY MOLD, TILING SYSTEM, AND METHOD

(71) Applicant: LEIA Inc., Menlo Park, CA (US)

(72) Inventors: Emeline Soichi, Menlo Park, CA (US); Sonny Vo, Menlo Park, CA (US); Zhen Peng, Menlo Park, CA (US); Fei Gao, Menlo Park, CA (US)

(21) Appl. No.: 18/720,475

(22) PCT Filed: Dec. 22, 2021
(86) PCT No.: PCT/US2021/064772

§ 371 Date: Jun. 14, 2024

(51) Int. Cl. G03F 7/00; B82Y 40/00

(52) U.S. Cl. CPC G03F 7/0002; B82Y 40/00

(57) ABSTRACT

A nanoimprint lithography mold, nanoimprint lithography tiling system, and method of dicing a nanoimprint lithography substrate employ a nanoimprint lithography mold having a precision edge and an undercut sidewall. The precision edge has nanoscale roughness and is adjacent to a top surface of the nanoimprint lithography mold at a predetermined distance from a feature of the nanoimprint lithography mold. The undercut sidewall extends from the precision edge to a bottom surface of the nanoimprint lithography mold. The undercut sidewall has a surface that is angled away from the precision edge and toward a center of the nanoimprint lithography mold. The precision edge and the undercut sidewall define a side of the nanoimprint lithography mold that can be abutted with corresponding sides of one or more other nanoimprint lithography molds.

### CROSS-REFERENCE TO RELATED APPLICATIONS

N/A.

### STATEMENT REGARDING FEDERALLY SPONSORED RESEARCH OR DEVELOPMENT

N/A

### BACKGROUND

Electronic displays are a nearly ubiquitous medium for communicating information to users of a wide variety of devices and products. Among the most commonly found electronic displays are the cathode ray tube (CRT), plasma display panels (PDP), liquid crystal displays (LCD), electroluminescent displays (EL), organic light emitting diode (OLED) and active matrix OLEDs (AMOLED) displays, electrophoretic displays (EP) and various displays that employ electromechanical or electrofluidic light modulation (e.g., digital micromirror devices, electrowetting displays, etc.). Many of these modern displays require high precision manufacturing to fabricate various display structures and elements.

Imprint lithography, including nanoimprint lithography, is among a number of fabrication techniques for producing various structures and elements associated with modern electronic displays. In particular, nanoimprint lithography generally excels at providing sub-micrometer or nanoscale features having very high precision and is readily adaptable to mass production. For example, nanoimprint lithography may be used to create a stamp or mold having nano-scale features by aggregating together or tiling wafers having nanoscale imprint patterns. The mold master may be used in nanoimprint lithography to imprint patterns onto a receiving substrate. Further, various high-volume fabrication methodologies, including but not limited to roll-to-roll imprinting, may be used in conjunction with nanoimprint lithography and a mold master for mass production. However, providing sub-micrometer or nanoscale feature precision over a large-area mold master may be problematic. In particular, maintaining nanoscale precision across the large-area mold master may be hampered, in practice, if nanoscale features extend beyond a boundary of a single wafer or device.

### BRIEF DESCRIPTION OF THE DRAWINGS

Various features of examples and embodiments in accordance with the principles described herein may be more readily understood with reference to the following detailed description taken in conjunction with the accompanying drawings, where like reference numerals designate like structural elements, and in which:

FIG. 1A illustrates perspective view of a nanoimprint lithography mold in an example, according to an embodiment consistent with the principles described herein.

FIG. 1B illustrates cross-sectional view of a nanoimprint lithography mold in an example, according to an embodiment consistent with the principles described herein.

FIG. 1C illustrates cross-sectional view of a nanoimprint lithography mold in an example, according to another embodiment consistent with the principles described herein.

FIG. 2 illustrates cross-sectional view of a nanoimprint lithography mold in an example, according to an embodiment consistent with the principles described herein.

FIG. 3A illustrates a perspective view of a nanoimprint lithography tiling system in an example, according to an embodiment consistent with the principles described herein.

FIG. 3B illustrates a cross-sectional view of a nanoimprint lithography tiling system in an example, according to an embodiment consistent with the principles described herein.

FIG. 3C illustrates a cross-sectional view of a nanoimprint lithography tiling system in an example, according to another embodiment consistent with the principles described herein.

FIG. 4 illustrates a flow chart of a method of dicing a nanoimprint lithography substrate to provide a nanoimprint lithography mold in an example, according to an embodiment consistent with the principles described herein.

FIGS. 5A-5G illustrate cross-sectional views of dicing a nanoimprint lithography substrate in an example, according to an embodiment of the principles described herein.

Certain examples and embodiments have other features that are one of in addition to and in lieu of the features illustrated in the above-referenced figures. These and other features are detailed below with reference to the above-referenced figures.

### DETAILED DESCRIPTION

Examples and embodiments in accordance with the principles described herein relate to a nanoimprint lithography and more particularly to nanoimprint lithography molds. In particular, embodiments of the principles described may facilitate using nanoimprint lithography in the fabrication nanoscale features on devices that are larger than available substrates used to provide a nanoimprint lithography mold. In some embodiments, a nanoimprint lithography mold is provided having a precision edge that allows adjacent nanoimprint lithography molds to abut one another in precise manner. Moreover, the precise spacing may also provide a precise spacing distance between nanoscale features of the tiled nanoimprint lithography molds. According to various embodiments, issues that may arise when nanoimprint lithography molds are tiled together or used for stamp-and-repeat nanoimprint lithography may be addressed. These issues may include, but not limited to, issues that may affect a spacing between the structures between abutted sections individual nanoimprint lithography molds during tiling as well as concerns regarding surface roughness of edges of the tiled nanoimprint lithography molds.

In particular, embodiments herein may address these issues by providing a precision edge that may be formed in the nanoimprint lithography mold using any nanotechnology process. By using nanotechnology processes to form the precision edge, the precision edge may have essentially nanoscale roughness. Moreover, the precision edge may be adjacent to a top surface of the nanoimprint lithography mold and at a predetermined distance from a feature of the nanoimprint lithography mold. Further, an undercut sidewall may be formed that extends from the precision edge towards a bottom surface of the nanoimprint lithography mold that is opposite the top surface of the nanoimprint lithography mold to further facilitate tiling. In particular, the undercut sidewall may have a surface that is angled away from the precision edge towards a center or central portion of the nanoimprint lithography mold. A combination of the precision edge and the undercut sidewall may define a side of the nanoimprint lithography mold. According to various embodiments, the precision edge may establish a spacing between nanoscale features on either side of boundary between abutted or tiled nanoimprint lithography molds, while the undercut sidewall ensures that surface roughness of the sidewall does not interfere with the spacing.

In further embodiments, a nanoimprint lithography tiling system is provided that may include multiple nanoimprint lithography molds. In an embodiment, a first nanoimprint lithography mold may have a precision edge and an undercut sidewall. A second or other nanoimprint lithography mold may have a precision edge and an undercut sidewall. The precision edges of the first and second nanoimprint lithography molds may be configured to abut one another in order to provide a tiled nanoimprint lithography master. In various embodiments, each of the precision edges of the nanoimprint lithography molds may have nanoscale roughness and be disposed a predetermined distance from a feature of a respective one of the nanoimprint lithography molds. In other embodiments, the precision edge may be used in conjunction with step-and-repeat or stamp-and-repeat fabrication methodologies. In particular, a single nanoimprint lithography mold (i.e., a master) may be employed to create multiple copies using nanoimprint lithography where the precision edge facilitates precise placement of adjacent copies using a step-and-repeat or stamp-and-repeat process. That is, the nanoscale roughness of the precision edge may mitigate an effect of the edge during these processes, especially with respect to a stitch interface between copies. Moreover, according to either of these embodiments, the undercut side walls may be angled away from the precision edges to ensure that an inter-feature distance between the features of respective ones of the nanoimprint lithography molds is determined by the abutted precision edges within the tiled nanoimprint lithography master or during step-and-repeat or stamp-and-repeat fabrication.

Herein, a ‘light guide’ is defined as a structure that guides light within the structure using total internal reflection. In particular, the light guide may include a core that is substantially transparent at an operational wavelength of the light guide. The term ‘light guide’ generally refers to a dielectric optical waveguide that employs total internal reflection to guide light at an interface between a dielectric material of the light guide and a material or medium that surrounds that light guide. By definition, a condition for total internal reflection is that a refractive index of the light guide is greater than a refractive index of a surrounding medium adjacent to a surface of the light guide material. In some embodiments, the light guide may include a coating in addition to or instead of the aforementioned refractive index difference to further facilitate the total internal reflection. The coating may be a reflective coating, for example. The light guide may be any of several light guides including, but not limited to, one or both of a plate or slab guide and a strip guide.

Further herein, the term ‘plate’ when applied to a light guide as in a ‘plate light guide’ is defined as a piece-wise or differentially planar layer or sheet, which is sometimes referred to as a ‘slab’ guide. In particular, a plate light guide is defined as a light guide configured to guide light in two substantially orthogonal directions bounded by a top surface and a bottom surface (i.e., opposite surfaces) of the light guide. Further, by definition herein, the top and bottom surfaces are both separated from one another and may be substantially parallel to one another in at least a differential sense. That is, within any differentially small section of the plate light guide, the top and bottom surfaces are substantially parallel or co-planar.

In some embodiments, the plate light guide may be substantially flat (i.e., confined to a plane) and therefore, the plate light guide is a planar light guide. In other embodiments, the plate light guide may be curved in one or two orthogonal dimensions. For example, the plate light guide may be curved in a single dimension to form a cylindrical shaped plate light guide. However, any curvature has a radius of curvature sufficiently large to ensure that total internal reflection is maintained within the plate light guide to guide light.

Herein, a ‘diffraction grating’ is generally defined as a plurality of features (i.e., diffractive features) arranged to provide diffraction of light incident on the diffraction grating. In some examples, the plurality of features may be arranged in a periodic or quasi-periodic manner. For example, the diffraction grating may include a plurality of features (e.g., a plurality of grooves or ridges in a material surface) arranged in a one-dimensional (1D) array. In other examples, the diffraction grating may be a two-dimensional (2D) array of features. The diffraction grating may be a 2D array of bumps on or holes in a material surface, for example.

As such, and by definition herein, the ‘diffraction grating’ is a structure that provides diffraction of light incident on the diffraction grating. If the light is incident on the diffraction grating from a light guide, the provided diffraction or diffractive scattering may result in, and thus be referred to as, ‘diffractive coupling’ in that the diffraction grating may couple light out of the light guide by diffraction. The diffraction grating also redirects or changes an angle of the light by diffraction (i.e., at a diffractive angle). In particular, as a result of diffraction, light leaving the diffraction grating generally has a different propagation direction than a propagation direction of the light incident on the diffraction grating (i.e., incident light). The change in the propagation direction of the light by diffraction is referred to as ‘diffractive redirection’ herein. Hence, the diffraction grating may be understood to be a structure including diffractive features that diffractively redirects light incident on the diffraction grating and, if the light is incident from a light guide, the diffraction grating may also diffractively couple out the light from the light guide.

Further, by definition herein, the features of a diffraction grating are referred to as ‘diffractive features’ and may be one or more of at, in, and on a material surface (i.e., a boundary between two materials). The surface may be a surface of a light guide, for example. The diffractive features may include any of a variety of structures that diffract light including, but not limited to, one or more of grooves, ridges, holes and bumps at, in or on the surface. For example, the diffraction grating may include a plurality of substantially parallel grooves in the material surface. In another example, the diffraction grating may include a plurality of parallel ridges rising out of the material surface. The diffractive features (e.g., grooves, ridges, holes, bumps, etc.) may have any of a variety of cross sectional shapes or profiles that provide diffraction including, but not limited to, one or more of a sinusoidal profile, a rectangular profile (e.g., a binary diffraction grating), a triangular profile and a saw tooth profile (e.g., a blazed grating).

Further, as used herein, the article ‘a’ is intended to have its ordinary meaning in the patent arts, namely ‘one or more’. For example, ‘a feature’ means one or more features and as such, ‘the feature’ means ‘feature(s)’ herein. Also, any reference herein to ‘top’, ‘bottom’, ‘upper’, ‘lower’, ‘up’, ‘down’, ‘front’, back’, ‘first’, ‘second’, ‘left’ or ‘right’ is not intended to be a limitation herein. Herein, the term ‘about’ when applied to a value generally means within the tolerance range of the equipment used to produce the value, or may mean plus or minus 10%, or plus or minus 5%, or plus or minus 1%, unless otherwise expressly specified. Further, the term ‘substantially’ as used herein means a majority, or almost all, or all, or an amount within a range of about 51% to about 100%. Moreover, examples herein are intended to be illustrative only and are presented for discussion purposes and not by way of limitation.

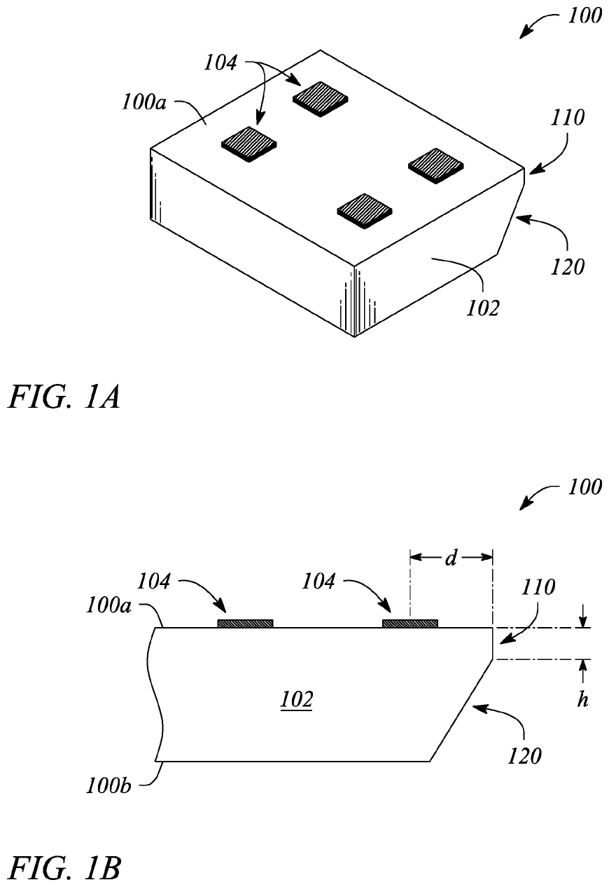

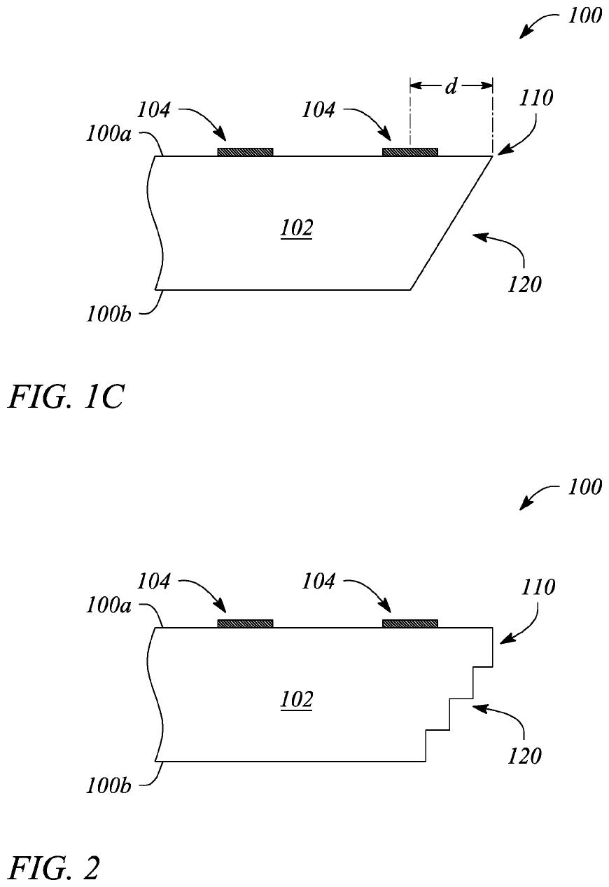

According to some embodiments of the principles described herein, a nanoimprint lithography mold is provided. FIG. 1A illustrates perspective view of a nanoimprint lithography mold 100 in an example, according to an embodiment consistent with the principles described herein. FIG. 1B illustrates cross-sectional view of a nanoimprint lithography mold 100 in an example, according to an embodiment consistent with the principles described herein. FIG. 1C illustrates cross-sectional view of a nanoimprint lithography mold 100 in an example, according to another embodiment consistent with the principles described herein.

The nanoimprint lithography mold 100 comprises a substrate 102 (e.g., a nanoimprint lithography substrate) that includes one or more features 104 disposed on the substrate 102, e.g., on a surface of the substrate 102 such as a top surface 100a, as illustrated. The features 104 may include any of a variety of structures having one or both of microscale and nanoscale characteristics or dimensions. For example, the features 104 may include, but are not limited to, various structures used to define optical elements on a device formed according to nanoimprint lithography using the nanoimprint lithography mold 100. Optical elements that may be formed by nanoimprint lithography using the features 104 on the substrate 102 of the nanoimprint lithography mold 100 may include diffraction gratings used to scatter light from a light guide, for example. In these examples, the features 104 may be a mirror image of the diffraction grating being formed using nanoimprint lithography. According to various embodiments, the substrate 102 may be semiconductor substrate such as, but not limited to, a silicon substrate or silicon carbide substrate. The nanoimprint lithography that employs the nanoimprint lithography mold 100 may be used to form light guides for electronic displays that may be used for various types of electronic devices.

As illustrated, the nanoimprint lithography mold 100 comprises a precision edge 110 along the substrate 102 having nanoscale roughness. That is, the edge of the substrate 102 of the nanoimprint lithography mold 100 has an edge that is the precision edge 110. The precision edge 110 is disposed adjacent to the top surface 100a of the nanoimprint lithography mold 100, as illustrated. In addition, the precision edge 110 is disposed at a at a predetermined distance d from a feature 104 of the nanoimprint lithography mold. For example, the feature 104 may be on or at the top surface 100a, as illustrated.

In some embodiments, the precision edge 110 extends from the top surface 100a toward a bottom surface 100b of the nanoimprint lithography mold 100 and has an extent h that is greater than about one hundred micrometers (100 μm) measured from the top surface 100a. For example, the extent h may be about one hundred fifty micrometers (150 μm). Other embodiments, the extent h of the precision edge may less than 100 μm. For example, the extent h may be about ten micrometers (10 μm). In yet other embodiments, the extent h may be greater than about 10 μm, or greater than about twenty micrometers (20 μm), or greater than about thirty micrometers (30 μm), or greater than about fifty micrometers (50 μm), or greater than about seventy five micrometers (75 μm). In general, the extent h may be chosen to balance durability of the precision edge 110 against manufacturability and yield. In some of these embodiments, the precision edge 110 may be perpendicular or substantially perpendicular to the top surface 100a of the nanoimprint lithography mold 100.

In other embodiments, the precision edge 110 is or forms a ‘knife edge’ at the top surface 100a. That is, the precision edge 110 may have an extent that is substantially less than ten micrometers (10 μm). FIG. 1C illustrates an example of the precision edge 110 as a knife edge. In various embodiments, the precision edge 110 may be formed using any of a variety of nanotechnology processes. Examples of such nanoscale process include, but are not limited to, deep reactive-ion etching processes such as a Bosch process. In particular, various deep reactive-ion etching processes may facilitate forming the precision edge 110 with an extent h that is relatively large, e.g., greater than about 50 μm or 100 μm.

The nanoimprint lithography mold 100 illustrated in FIGS. 1A-1C further comprises an undercut sidewall 120 extending from the precision edge 110 to a bottom surface 100b of the nanoimprint lithography mold 100. As illustrated, the undercut sidewall 120 has a surface (i.e., a slanted surface) that is angled away from the precision edge 110 and toward a central portion of the nanoimprint lithography mold 100, e.g., toward the feature 104. As such, the extent h of the precision edge 110 may determine a beginning of the undercut sidewall 120. In embodiments with a precision edge 110 that forms a knife edge, the undercut sidewall 120 may extend from the bottom surface 100b to or nearly to the top surface 100a of the nanoimprint lithography mold 100, as illustrated in FIG. 1C. In some embodiments, the precision edge 110 may be formed at the same time or by the process used to form the undercut sidewall 120. According to various embodiments, a combination of the precision edge 110 and the undercut sidewall 120 define a side of the nanoimprint lithography mold 100.

According to some embodiments, the undercut sidewall 120 comprises a gradual taper from an end adjacent to the precision edge 110 to an end at the bottom surface 100b of the nanoimprint lithography mold 100. In these embodiments, the gradual taper is generally toward a center of the nanoimprint lithography mold 100 and away from the precision edge 110. According to various embodiments, the gradual taper provides the surface of the undercut sidewall 120. FIGS. 1B and 1C illustrate the undercut sidewall 120 comprising a gradual taper.

In other embodiments, the undercut sidewall 120 comprises a profile that is stepped back (i.e., a ‘stepped back profile’) from the precision edge 110 toward a center of the nanoimprint lithography mold. The stepped back profile provides the surface of the undercut sidewall 120. FIG. 2 illustrates cross-sectional view of a nanoimprint lithography mold 100 in an example, according to an embodiment consistent with the principles described herein. As illustrated, the nanoimprint lithography mold 100 comprises the precision edge 110 and the undercut sidewall 120. The undercut sidewall 120 comprises the stepped back profile that extends from the precision edge 110 to the bottom surface of the nanoimprint lithography mold 100, as illustrated in FIG. 2. Also illustrated in FIG. 2 is the feature 104 in the top surface 100a of the nanoimprint lithography mold 100 along with the substrate 102.

According to some embodiments, the precision edge 110 has nanoscale roughness. In particular, the precision edge 110 may have an average roughness value of less than about five micrometers (5 μm). For example, the average roughness value may be between about one micrometer (1 μm) and about 5 μm, in various embodiments. Additionally, an average roughness of the undercut sidewall 120 may be less than about half of a distance from the undercut sidewall to a plane of the precision edge 110. By limiting the average roughness of the undercut sidewall 120 in this manner, any roughness of the undercut sidewall 120 is unlikely to extend beyond the precision edge 110.

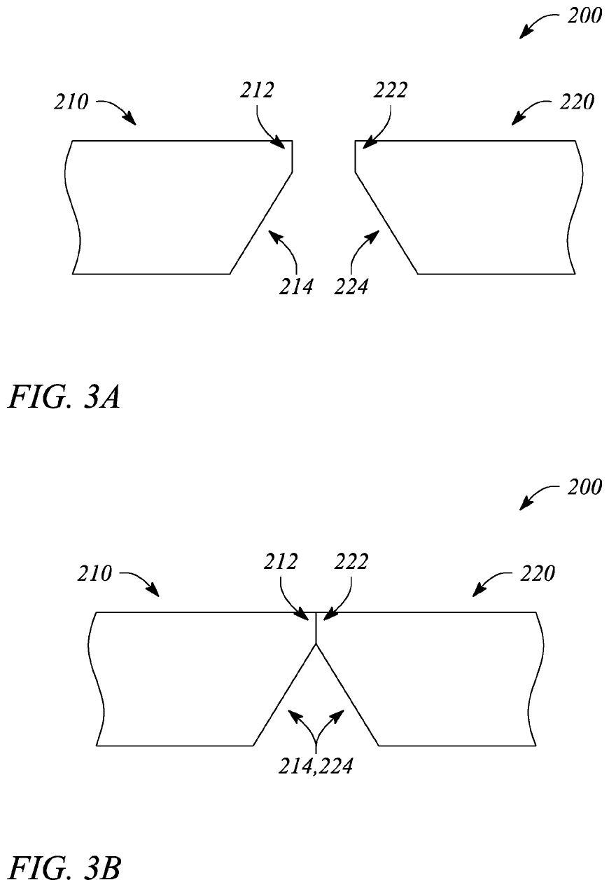

According to other embodiments of the principles described herein, a nanoimprint lithography tiling system is provided. FIG. 3A illustrates a cross-sectional view of a nanoimprint lithography tiling system 200 in an example, according to an embodiment consistent with the principles described herein. FIG. 3B illustrates a cross-sectional view of a nanoimprint lithography tiling system 200 of FIG. 3B in an example, according to an embodiment consistent with the principles described herein. The nanoimprint lithography tiling system 200 is configured to provide a tiled nanoimprint lithography master 202 (FIG. 3B), according to various embodiments.

As illustrated in FIG. 3A, the nanoimprint lithography tiling system 200 comprises a nanoimprint lithography mold 210 having a precision edge 212 and an undercut sidewall 214. The nanoimprint lithography tiling system 200 further comprises another nanoimprint lithography mold 220 having a precision edge 222 and an undercut sidewall 224. According to various embodiments, the precision edges 212, 222 of the nanoimprint lithography molds 210, 220 are configured to abut one another to provide a tiled nanoimprint lithography master 202. FIG. 3B illustrates the nanoimprint lithography tiling system 200 after the nanoimprint lithography molds 210, 220 have been abutted at the precision edges 212, 222. According to various embodiments, the precision edges 212, 222 and the undercut sidewalls 214, 224 are configured to ensure that an inter-feature distance between the features of respective ones of the nanoimprint lithography molds 210, 220 is determined by abutted precision edges 212, 222 within the tiled nanoimprint lithography master 202.

According to some embodiments, the nanoimprint lithography molds 210, 220 of the nanoimprint lithography tiling system 200 may be substantially similar to the nanoimprint lithography mold 100 described above. For example, the precision edges 212, 222 of the nanoimprint lithography molds 210, 220 may be substantially similar to the precision edge 110 of the above-described nanoimprint lithography mold 100. Likewise, the undercut sidewalls 214, 224 of the nanoimprint lithography molds 210, 220 may be substantially similar to the undercut sidewall 120 described above with respect to nanoimprint lithography mold 100. In particular, each of the precision edges 212, 222 of the respective nanoimprint lithography molds 210, 220 have nanoscale roughness and are disposed a predetermined distance from a feature of respective ones of the nanoimprint lithography molds 210, 220. Further, the undercut sidewalls 214, 224 of each of the nanoimprint lithography molds 210, 220 are angled away from the precision edges 212, 222, in various embodiments.

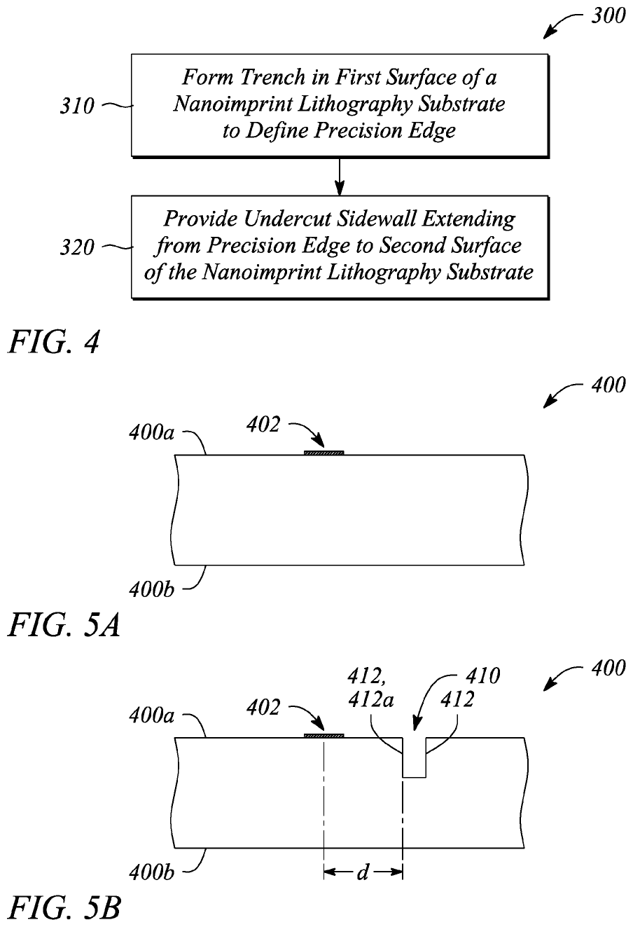

According to other embodiments of the principles described herein, a method of dicing a nanoimprint lithography substrate to provide a nanoimprint lithography mold is provided. FIG. 4 illustrates a flow chart of a method 300 of dicing a nanoimprint lithography substrate to provide a nanoimprint lithography mold in an example, according to an embodiment consistent with the principles described herein.

As illustrated, the method 300 of dicing a nanoimprint lithography substrate comprises forming 310 a trench in a first surface of the nanoimprint lithography substrate. According to various embodiments, the trench defines a precision edge of the nanoimprint lithography mold. In some embodiments, the precision edge defined by the trench during forming 310 the trench may be substantially similar to the precision edge 110 described above with respect to the nanoimprint lithography mold 100. Further, according to some embodiments, the nanoimprint lithography substrate may be substantially similar to the substrate 102 of the nanoimprint lithography mold 100. In particular, the precision edge defined by the trench during forming 310 the trench has nanoscale roughness and is located a predetermined distance from a feature of the nanoimprint lithography mold on the nanoimprint lithography substrate.

The method 300 of dicing a nanoimprint lithography substrate illustrated in FIG. 4 further comprises providing 320 an undercut sidewall extending from the precision edge to a second surface of the nanoimprint lithography substrate opposite the first surface. In some embodiments, the undercut sidewall forms a slanted surface that tapers away from the precision edge and toward a center of the nanoimprint lithography mold. In various embodiments, an average distance from the feature to the undercut sidewall is less than the predetermined distance of the precision edge from the feature after providing 320 the undercut sidewall. In some embodiments, the undercut sidewall that results from providing 320 the undercut sidewall may be substantially similar to the undercut sidewall 120 of the above-described nanoimprint lithography mold 100.

In some embodiments, forming 310 the trench comprises providing the trench having a depth of greater than 100 micrometers (100 μm). In other embodiments, the depth of the trench provided by forming 310 the trench may be less than 100 μm. For example, the trench may be greater than about ten micrometers (10 μm), or greater than about twenty micrometers (20 μm), or greater than about thirty micrometers (30 μm), or greater than about fifty micrometers (50 μm), or greater than about seventy five micrometers (75 μm).

In some embodiments, forming 310 the trench may provide a trench having a sidewall that is perpendicular to the first surface of the nanoimprint lithography substrate. In these embodiments, the trench sidewall defines the precision edge that is perpendicular to the first surface of the nanoimprint lithography substrate. In some embodiments, forming 310 the trench comprising performing a deep reactive-ion etching in the first surface of the nanoimprint lithography substrate. The deep reactive-ion etching may be performed using a Bosch process, for example. In another embodiment, forming 310 the trench may comprise wet etching the first surface of the nanoimprint lithography substrate. For example, when the nanoimprint lithography substrate comprises silicon (e.g., a silicon wafer), wet etching using potassium hydroxide (KOH) may be used to form 310 the trench. Any of a variety of other etching processes may also be used to form 310 the trench without departing from the scope of the principles described herein.

In some embodiments, providing 320 the undercut sidewall comprises employing stealth laser dicing at a location offset from the precision edge toward a central portion of the nanoimprint lithography mold. In some embodiments, providing 320 the undercut sidewall comprises employing wafer dicing saw to cut a slot in a backside of the nanoimprint lithography mold and at a location offset from the precision edge toward a center of the nanoimprint lithography mold.

In some embodiments (not illustrated), a method of providing a tiled nanoimprint lithography master is provided. The method of providing a tiled nanoimprint lithography master comprises the method 300 of dicing a nanoimprint substrate. The method of providing a tiled nanoimprint lithography master further comprises abutting the precision edge of the nanoimprint lithography mold with a precision edge of another nanoimprint lithography mold to provide the tiled nanoimprint lithography master, In various embodiments, the undercut sidewalls are angled away from the respective abutted precision edges to ensure that the nanoscale roughness of abutted precision edges determine an inter-feature distance between the features of the respective nanoimprint lithography molds within the tiled nanoimprint lithography master.

### Examples

Several examples of dicing a nanoimprint lithography substrate according to the method 300 are presented below. The examples illustrate results of employing the aforementioned method, by way of example and not limitation.

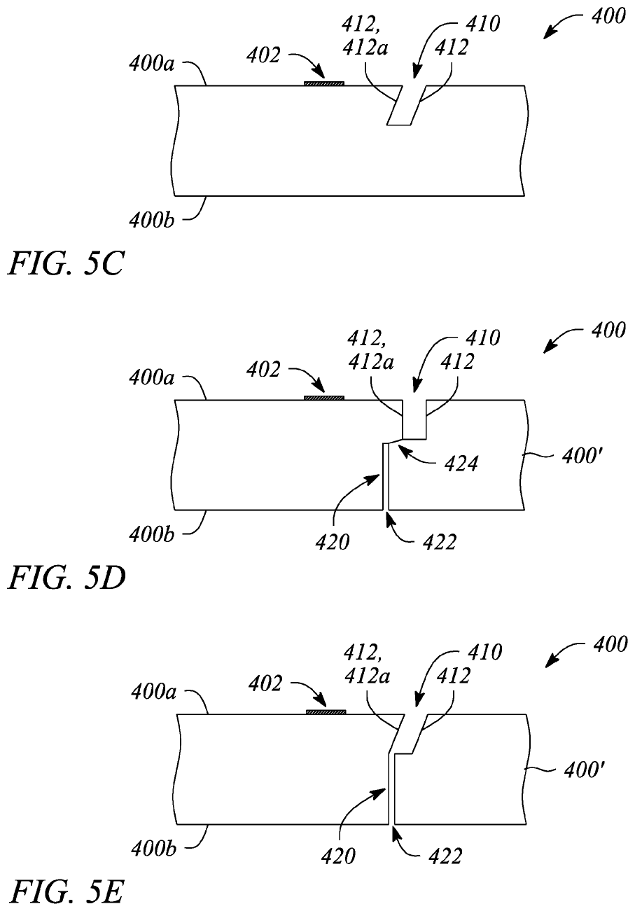

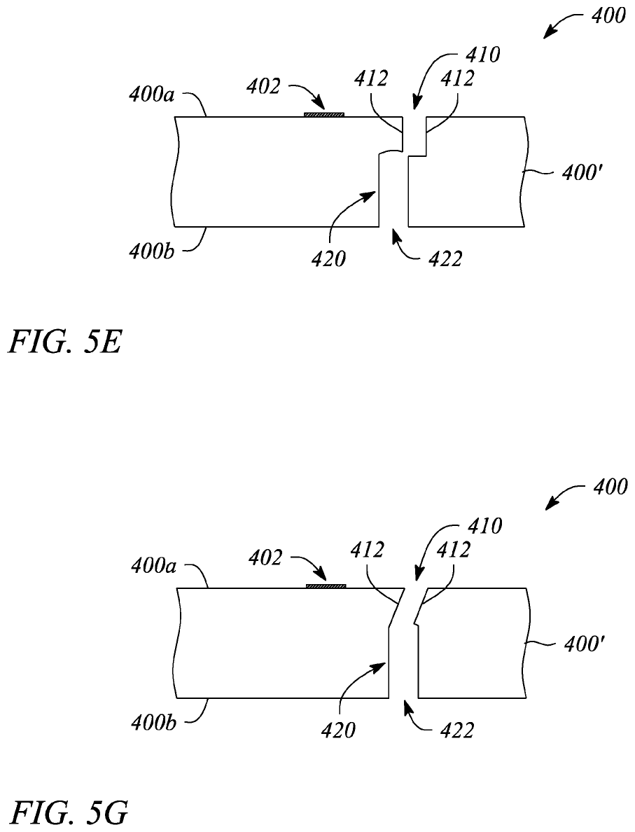

FIGS. 5A-5G illustrate cross-sectional views of dicing a nanoimprint lithography substrate 400 in an example, according to an embodiment of the principles described herein. As illustrated, a nanoimprint lithography mold may be provided when dicing the nanoimprint lithography substrate 400 is completed. In some embodiments, the nanoimprint lithography substrate 400 may be substantially similar to the substrate 102 of the nanoimprint lithography mold 100, as described above. As illustrated in FIGS. 5A-5F, the nanoimprint lithography substrate 400 includes a feature 402 such as, but not limited to, a microscale or nanoscale structure (e.g., a diffraction grating).

The feature 402 may be provided either in a surface of the nanoimprint lithography substrate 400 (as illustrated) or in a layer (not illustrated) on a surface of the nanoimprint lithography substrate 400. For example, the layer may comprise a layer silicon dioxide (SiO₂) on a surface of nanoimprint lithography substrate 400 that comprises silicon. FIG. 5A illustrates the feature 402 that has been etched or otherwise provided in a layer of silicon dioxide on a first surface 400a of the nanoimprint lithography substrate 400.

FIGS. 5B and 5C illustrate a trench 410 formed in the first surface 400a and extending toward a second surface 400b of the nanoimprint lithography substrate 400. FIG. 5B illustrates the trench 410 having sidewalls 412 that are perpendicular to the first surface 400a, while FIG. 5C illustrate the trench 410 having slanted or angled sidewalls 412, by way of example and not limitation. In some embodiments, forming 310 the trench of the method 300 of dicing a nanoimprint lithography substrate may be used to form the trench 410 as illustrated in FIGS. 5B-5C.

In FIGS. 5B-5C, the trench 410 is illustrated at a predetermined distance d from the feature 402. In addition, the trench 410 has sidewalls with nanoscale roughness. According to various embodiments, one of the sidewalls 412 of the trench 410 (e.g., a first sidewall 412a) may become a precision edge of the nanoimprint lithography mold being formed once dicing the nanoimprint lithography substrate 400 is completed.

According to some embodiments, the trench 410 may have a width of between about fifty micrometers (50 μm) and about one hundred fifty micrometers (150 μm). However, the width of the trench 410 illustrated in FIGS. 5B-5C may be substantially any width and further the width may be dependent on the method used to form the trench 410. In some embodiments, the trench 410 may have a depth that is greater than about one hundred micrometers (100 μm). For example, a depth between about one hundred fifty micrometers (150 μm) and about three hundred fifty micrometers (350 μm) may be formed using reactive-ion etching (e.g., a Bosch process). In addition, reactive-ion etching such as, but not limited to, a Bosch process may be employed to provide the trench 410 of FIG. 5B having perpendicular sidewalls 412. The trench 410 illustrated in FIG. 5C having slanted sidewalls 412 may be provided by angled reactive-ion etching or by a wet etch process such as using potassium hydroxide (KOH) to etch silicon along a crystal boundary, for example.

FIGS. 5D and 5E illustrate an embodiment of providing an undercut sidewall 420 of a nanoimprint lithography mold being formed and completing the dicing of the nanoimprint lithography substrate 400. As illustrated, a laser may be used to provide a slot 422 extending from the second surface 400b to the trench 410. The slot 422 may be provided using a stealth laser technique, for example. In FIG. 5D where the trench 410 has perpendicular sidewalls 412, the slot 422 is offset away from the trench 410 and toward what will be a center of the nanoimprint lithography mold. In some embodiments, the offset may range from as little as five micrometers (5 μm) up to about fifty micrometers (50 μm) or more. The offset is configured to ensure that the undercut sidewall 420 is angled away from a precision edge of the nanoimprint lithography mold provided by the trench 410. For example, offsetting the slot 422 may result in an undercut sidewall 420 that is stepped back away from the precision edge represented by the first sidewall 412a. Also illustrated in FIG. 5D is a fracture that connects the slot 422 to the trench 410. The fracture may be a result of separating the nanoimprint lithography mold at a completion of dicing of the nanoimprint lithography substrate 400, for example.

In FIG. 5E where the trench 410 has angled sidewalls, the slot 422 need not be offset (e.g., as illustrated), since the angled sidewalls 412 of the trench 410 already ensure that the undercut sidewall 420 will be angled away from the precision edge. As illustrated by way of example and not limitation, the slot 422 connects with a bottom corner of the trench 410. However, even though the slot 422 is not offset from the trench 410, the undercut sidewall 420 is still stepped back away from the precision edge represented by the first sidewall 412a, as illustrated in FIG. 5E.

FIGS. 5F and 5G illustrates another embodiment of providing an undercut sidewall 420 of a nanoimprint lithography mold being formed and completing the dicing of the nanoimprint lithography substrate 400. As illustrated, a mechanical saw (e.g., a wafer saw) may be used to cut a slot 422 in the second surface 400b. As with the laser, the slot cut by the mechanical saw may offset away from the trench 410 and toward an eventual center of the nanoimprint lithography mold to ensure that the undercut sidewall 420 is angled away from the precision edge provided by the sidewall of the trench 410. In particular, FIG. 5F illustrates an example of the slot 422 made using the mechanical saw where the trench 410 has perpendicular sidewalls 412. As illustrated, a center of the slot 422 is offset from the trench 410. FIG. 5G illustrates an example of the slot 422 made using the mechanical saw where the trench 410 has slanted sidewalls 412.

Also illustrated in FIGS. 5D-5G is the nanoimprint lithography mold 430 that results from dicing the nanoimprint lithography substrate 400. The nanoimprint lithography mold 430 is to a left of the trench 410, while a portion 400′ of the nanoimprint lithography substrate 400 that may be discarded following dicing is illustrated to a right of the trench 410 in FIGS. 5D-5G.

Thus, there have been described examples and embodiments of a nanoimprint lithography mold, nano nanoimprint lithography tiling system, and a method of dicing a nanoimprint lithography substrate to provide a nanoimprint lithography mold having a precision edge and an undercut sidewall. It should be understood that the above-described examples are merely illustrative of some of the many specific examples that represent the principles described herein. Clearly, those skilled in the art can readily devise numerous other arrangements without departing from the scope as defined by the following claims.

What is claimed is:

1. A nanoimprint lithography mold comprising:
a precision edge having nanoscale roughness and being disposed adjacent to a top surface of the nanoimprint lithography mold at a predetermined distance from a feature of the nanoimprint lithography mold; and
an undercut sidewall extending from the precision edge to a bottom surface of the nanoimprint lithography mold, the undercut sidewall having a surface that is angled away from the precision edge and toward a central portion of the nanoimprint lithography mold,
wherein a combination of the precision edge and the undercut sidewall define a side of the nanoimprint lithography mold.

2. The nanoimprint lithography mold of claim 1, wherein the precision edge extends from the top surface toward a bottom surface of the nanoimprint lithography mold and has an extent that is greater than one hundred micrometers measured from the top surface.

3. The nanoimprint lithography mold of claim 2, wherein the precision edge is perpendicular to the top surface of the nanoimprint lithography mold.

4. The nanoimprint lithography mold of claim 1, wherein the undercut sidewall extends to the top surface of the nanoimprint lithography mold, the precision edge is a knife edge at the top surface.

5. The nanoimprint lithography mold of claim 1, wherein the undercut sidewall comprises a gradual taper from an end adjacent to the precision edge to an end at the bottom surface of the nanoimprint lithography mold, the gradual taper being toward a center of the nanoimprint lithography mold and providing the surface of the undercut sidewall.

6. The nanoimprint lithography mold of claim 1, wherein the undercut sidewall comprises a profile that is stepped back from the precision edge toward a center of the nanoimprint lithography mold to provide the surface of the undercut sidewall.

7. The nanoimprint lithography mold of claim 1, wherein the precision edge has an average roughness value of less than five micrometers, an average roughness of the undercut sidewall being less than about half of a distance from the undercut sidewall to a plane of the precision edge.

8. A nanoimprint lithography tiling system comprising:
a nanoimprint lithography mold having a precision edge and an undercut sidewall; and
another nanoimprint lithography mold having a precision edge and an undercut sidewall, the precision edges of the nanoimprint lithography molds being configured to abut one another to provide a tiled nanoimprint lithography master,
wherein each of the precision edges of the respective nanoimprint lithography molds have nanoscale roughness and are disposed a predetermined distance from a feature of respective ones of the nanoimprint lithography molds, the undercut sidewalls the respective nanoimprint lithography molds being angled away from the precision edges to ensure that an inter-feature distance between the features of respective ones of the nanoimprint lithography molds is determined by abutted precision edges within the tiled nanoimprint lithography master.

9. The nanoimprint lithography tiling system of claim 8, wherein the precision edges extend from a top surface toward a bottom surface of the nanoimprint lithography molds, an extent of the precision edges being greater than one hundred micrometers.

10. The nanoimprint lithography tiling system of claim 8, wherein the undercut sidewalls each comprise a gradual taper from an end adjacent to the precision edge to an end at a bottom surface of the nanoimprint lithography mold, the gradual taper being toward a central portion of respective ones of the nanoimprint lithography molds.

11. The nanoimprint lithography tiling system of claim 8, wherein an average roughness of the nanoscale roughness of the precision edges is less than five micrometers.

12. A method of dicing a nanoimprint lithography substrate to provide a nanoimprint lithography mold, the method comprising:
forming a trench in a first surface of the nanoimprint lithography substrate, the trench defining a precision edge of the nanoimprint lithography mold, the precision edge having nanoscale roughness and being located a predetermined distance from a feature of the nanoimprint lithography mold on the nanoimprint lithography substrate; and
providing an undercut sidewall extending from the precision edge to a second surface of the nanoimprint lithography substrate opposite the first surface, an average distance from the feature to the undercut sidewall being less than the predetermined distance of the precision edge from the feature.

13. The method of dicing a nanoimprint lithography substrate of claim 12, wherein forming the trench comprises providing the trench having a depth of greater than 100 micrometers.

14. The method of dicing a nanoimprint lithography substrate of claim 12, wherein forming the trench provides a trench having a sidewall that is perpendicular to the first surface, the trench sidewall defining the precision edge that is perpendicular to the first surface of the nanoimprint lithography substrate.

15. The method of dicing a nanoimprint lithography substrate of claim 12, wherein forming the trench comprises performing a deep reactive-ion etching in the first surface of the nanoimprint lithography substrate.

16. The method of dicing a nanoimprint lithography substrate of claim 15, wherein deep reactive-ion etching is performed using a Bosch process.

17. The method of dicing a nanoimprint lithography substrate of claim 12, wherein forming the trench comprises wet etching the first surface of the nanoimprint lithography substrate.

18. The method of dicing a nanoimprint lithography substrate of claim 12, wherein the undercut sidewall forms a slanted surface that tapers away from the precision edge and toward a center of the nanoimprint lithography mold.

19. The method of dicing a nanoimprint lithography substrate of claim 12, wherein providing the undercut sidewall comprises employing stealth laser dicing at a location offset from the precision edge toward a central portion of the nanoimprint lithography mold.

20. The method of dicing a nanoimprint lithography substrate of claim 12, wherein providing the undercut sidewall comprises employing wafer dicing saw to cut a slot in a backside of the nanoimprint lithography mold and at a location offset from the precision edge toward a center of the nanoimprint lithography mold.

21. A method of providing a tiled nanoimprint lithography master comprising the method of dicing a nanoimprint lithography substrate of claim 12, the method further comprising abutting the precision edge of the nanoimprint lithography mold with a precision edge of another nanoimprint lithography mold to provide the tiled nanoimprint lithography master, the undercut sidewalls being angled away from the respective abutted precision edges to ensure that the nanoscale roughness of abutted precision edges determine an inter-feature distance between the features of the respective nanoimprint lithography molds within the tiled nanoimprint lithography master.
